(19) United States
(12) Patent Application Publication
(10) Pub. No.: US 2006/0154184 A1
(43) Pub. Date: Jul. 13, 2006

(54) METHOD FOR REDUCING FEATURE LINE EDGE ROUGHNESS

(75) Inventors: Arpan P. Mahorowala, Bronxville, NY (US); Scott A. Bell, San Jose, CA (US); S. Dakshina Murthy, Bangalore (IN); Stacy A. Rasgon, Canoga Park, CA (US); Hongwen Yan, Somers, NY (US); Chih-Yuh Yang, San Jose, CA (US)

Correspondence Address: DELIO & PETERSON, LLC, 121 WHITNEY AVENUE, NEW HAVEN, CT, 06510, US

(73) Assignees: INTERNATIONAL BUSINESS MACHINES CORPORATION, Armonk, NY (US); ADVANCED MICRO DEVICES, INC., Sunnyvale, CA (US)

(21) Appl. No.: 10/905,596

(22) Filed: Jan. 12, 2005

(51) Int. Cl. G03F 7/00

(52) U.S. Cl. 430/323

(57) ABSTRACT

A method of patterning a feature in a substrate to reduce edge roughness comprises forming a resist layer overlying a substrate, exposing the resist layer to create an image of a feature, and developing the exposed resist layer to leave a portion of the resist layer that creates the image of the feature. The method then includes treating the exposed resist layer with a plasma to cure the portion of the resist layer creating the feature image. The plasma treatment has an ion bombardment level insufficient to substantially etch the underlying substrate. The method then includes etching the underlying substrate to create the feature.

### BACKGROUND OF THE INVENTION

1. Field of the Invention

The present invention relates generally to manufacturing processes requiring lithography and, more particularly, to the treatment of photoresists suitable for use in the production of microelectronic devices to reduce edge roughness of features produced by plasma etching.

2. Description of Related Art

Photolithography is used to expose resist layers over substrates used to create microelectronic devices. After the image has been developed, the remaining portion of the resist layer creates the image of the exposed feature, which is then used as a mask to etch underlying substrate materials. It is undesirable to have excessive line edge roughness in the final etched feature, i.e., along the walls of the feature. For example, in front end of the line (FEOL) processing, rough polysilicon gate profiles can affect the doping profiles in the source and drain regions, thereby altering device characteristics. Similarly, in back end of the line (BEOL) processing, it is difficult to obtain conformal liner coverage when the features patterned in the dielectric layer are rough. Poor liner conformality can cause copper voiding, increased resistivity and copper electromigration, all of which hurt chip performance.

Many factors contribute to line edge roughness. Rough photomask edges, image blurring due to lens imperfections, non-uniform distribution of photoacid in the exposed resist during post-exposure bake (PEB), for example, can all cause line edge roughness in the post-developed resist profiles. Etching processes can further create line edge roughness.

### SUMMARY OF THE INVENTION

Bearing in mind the problems and deficiencies of the prior art, it is therefore an object of the present invention to provide a method of transferring a photolithographically patterned feature via etching processes into a substrate with reduce line edge roughness.

It is another object of the present invention to provide a method of processing the resist layer during an etch process to reduce edge roughness of the subsequently etched feature.

It is another object of the present invention is to provide an improved curing of the photoresist layer that results in reduced line edge roughness in the etched feature.

Still other objects and advantages of the invention will in part be obvious and will in part be apparent from the specification.

The above and other objects, which will be apparent to those skilled in art, are achieved in the present invention which is directed to a method of patterning a feature in a substrate to reduce edge roughness comprising forming a resist layer overlying a substrate, exposing the resist layer to create an image of a feature, and developing the exposed resist layer to leave a portion of the resist layer that creates the image of the feature. The method then includes treating the exposed resist layer with a plasma to cure the portion of the resist layer creating the feature image. The plasma treatment has an ion bombardment level insufficient to substantially etch the underlying substrate. The method then includes etching the underlying substrate to create the feature.

Preferably, the method includes providing a plasma chamber and placing the resist layer and substrate in the plasma chamber, such that the curing and etching take place in the plasma chamber. The underlying substrate is etched using the cured portion of the resist layer as the etch mask.

The resist layer (typically uncured before plasma exposure) is exposed to the plasma, which may comprise of HBr or Hi, for example. The etching may be performed by further exposre to same/similar plasma, e.g. the same plasma employed to cure the resist layer portion, except at a higher ion bombardment level. The etching may be performed using inductive or capacitively-coupled etch tools.

The method may further include trimming the portion of the resist layer creating the feature image prior to cure. The resist may contain an inorganic species, e.g., a Si-containing bilayer resist.

The substrate in which the feature is to be etched may be on a front end of the line (FEOL) level or on a back end of the line (BEOL) level.

The substrate may comprise a polysilicon or metal layer with no hard mask layer between the resist layer and the polysilicon or metal layer. The substrate may also include a polysilicon layer and a hard mask layer between the resist layer and the polysilicon layer. In such case, the method further includes using the portion of the resist layer creating the feature image to etch openings in the hardmask layer, removing the resist layer portion, and using the etched hard mask layer to etch the polysilicon layer to create the feature.

Preferably, during the plasma treatment of the resist layer, the method includes selectively removing fast etching portions of the resist layer to leave a more uniformly etching resist layer.

### BRIEF DESCRIPTION OF THE DRAWINGS

The features of the invention believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIG. 1 is a perspective view of a portion of a layered stack comprising, from the bottom, silicon, polysilicon, hard mask, an anti-reflective coating (ARC) and a photoresist layer showing a latent image of a feature projected thereon.

FIG. 2 is a perspective view of the stack of FIG. 1, showing the resist layer developed with the feature image.

FIG. 3 is a perspective view of the stack of FIG. 2, showing the ARC etched through the resist layer.

FIG. 4 is a perspective view of the stack of FIG. 3 showing the hard mask layer etched through the resist and ARC.

FIG. 5 is a perspective view of the stack of FIG. 4, after the resist and ARC layers have been removed.

FIG. 6 is a perspective view of the stack of FIG. 5, after the hard mask layer has been used to etch the polysilicon layer.

### DESCRIPTION OF THE PREFERRED EMBODIMENT(s)

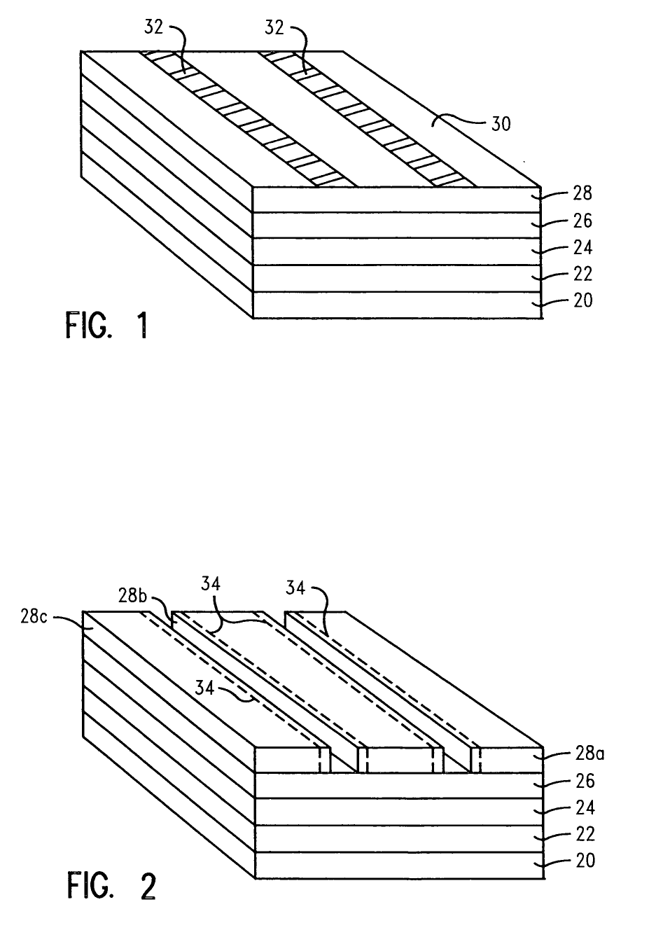

In describing the preferred embodiment of the present invention, reference will be made herein to FIGS. 1-6 of the drawings in which like numerals refer to like features of the invention.

The present invention enables the reduction of the line edge roughening phenomenon of the final etch feature by curing the resist layer prior to or during the etch step. During conventional etching processes, high ion bombardment energies can facet and roughen resist features, such that the roughness may transfer into the substrate. The method of the present invention allows the patterning of smoother features without disrupting the existing process flow. The benefits achieved herein are over and above those obtained by optimizing the existing lithography and etching steps.

The present invention uses resist curing as a method to reduce roughening the resist during etch, which typically then translates to smoother etched profiles in the substrate. Line edge roughness reduction is demonstrated by curing the resist preferably in a plasma etch chamber using a low bias plasma, i.e., one in which the ion bombardment level is reduced so that it is insufficient to substantially etch the underlying substrate. Preferably, the plasma comprises HBr, although Hi may also be employed.

As shown in FIG. 1, there are stacked overlying layers in contact with each other comprising lower silicon layer 20, followed by polysilicon layer 22, hard mask layer 24, anti reflective coating (ARC) layer 26, and photoresist layer 28. In order to achieve the ultimate goal of creating a feature in polysilicon layer 22, an image of the feature is initially projected by radiation, for example, light (UV or visible) through a mask to create a latent image 32 on the surface 30 of resist layer 28. Those portions of the resist whose energy exceed a threshold energy of chemical bonds in the photo active component (PAC) of the resist material create a latent image in the resist film. In some resist systems, the latent image is formed directly by the PAC. In others, (so called acid catalyzed resist), the photochemical interaction first generates acid which reacts with other resist components during a post exposure bake to form the latent image. In either case, the latent image marks the volume of resist material that either is removed during the development process (in the case of positive resist) or remains after development (in the case of negative resist) to create a three dimensional pattern in the resist film. In the example shown, a positive resist is employed so that the latent image 32 represents an area (or volume) that is to be removed from the resist layer.

The invention may be used with a wide variety of resist materials, although it is particularly useful with resists that do not contain inorganic species, e.g., Si-containing bilayer resists.

After developing the latent image, the image area is removed to leave the open spaces in the resist layer, breaking it into resist segments 28a, 28b and 28c as shown in FIG. 2. After development and the formation of the desired image of the feature in the remaining resist portions, the resist layer is then cured in accordance with the present invention. Preferably, the resist pattern is cured within a plasma etch chamber that is to be subsequently used to etch the polysilicon gate stack or any other substrate chosen. In such chamber, preferably the same type of plasma is employed for curing the resist layer as is employed for etching the remaining stack layers. Optionally, different plasma may be employed for each of the two steps. Also, etching may be performed using either inductive or capacitively-coupled plasma etch tools.

During the plasma curing of the resist layer, the plasma is permitted to contact the resist layer, but the level of ion bombardment is reduced so that it does not substantially etch the layers below the resist layer. The plasma cure and ion bombardment is however sufficient to reduce the number of C═O and C—O bonds in the resist. While not being bound by theory, it is believed that the elimination of these single and double carbon/oxygen bonds, which also results in some thickness loss, makes the resist more uniformly etch resistant since these from the faster etching components. This more homogenized remaining resist (from the perspective of etching) results in its more uniform subsequent etching and therefore a reduced and less prone to line edge roughness. The smooth resist profiles translate into smoother patterns in the final etched substrate.

An example of the curing and etching parameters employed on a wafer in accordance with the present invention employs an HBr plasma etch process. After striking/clamping the wafer, the plasma is run at the following conditions −7 mT, 1200 W top power, 0 W bias power, 300 sccm HBr, 60 C bottom electrode temperature, 8T backside He flow, 40 s duration. The wafer is removed from the clamp under an inert Ar atmosphere. The ion bombardment level in this plasma treatment is insufficient to substantially etch the underlying substrate.

Subsequent to the curing of the resist layer, the etching proceeds as normal. An optional trimming of the resist layer to lines 34 may be performed, as shown in FIG. 2.

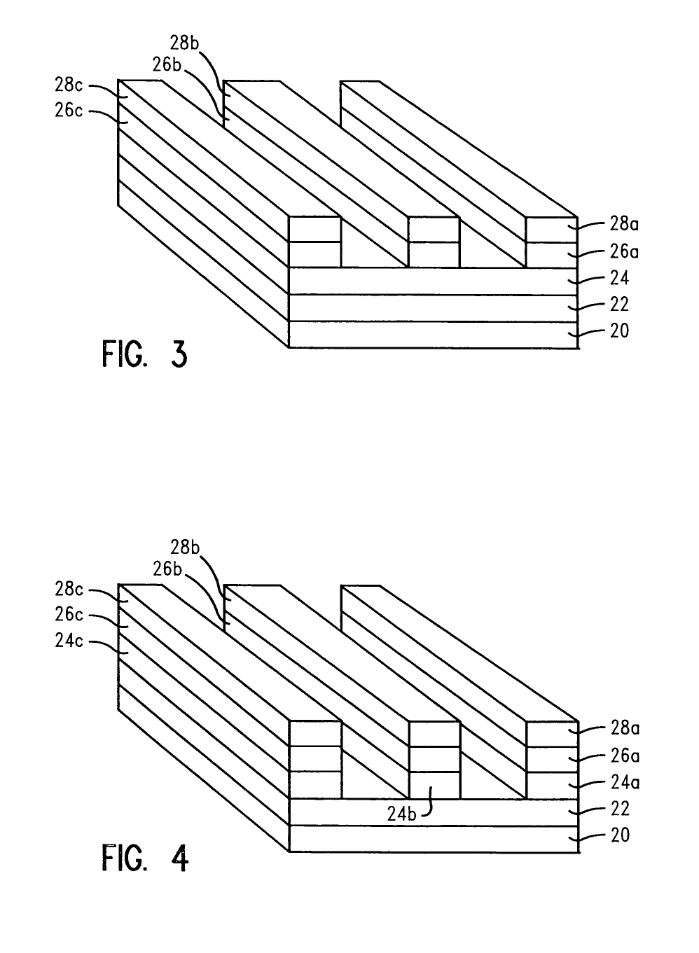

As shown in FIG. 3, the remaining resist portions 28a and 28b and 28c are used to mask and etch the image feature in the ARC layer resulting in conforming ARC portions 26a, 26b and 26c, which are then used to mask the etching of the optional hard mask layer (FIG. 4) to result in the feature forming corresponding hard mask layer portions 24a, 24b and 24c.

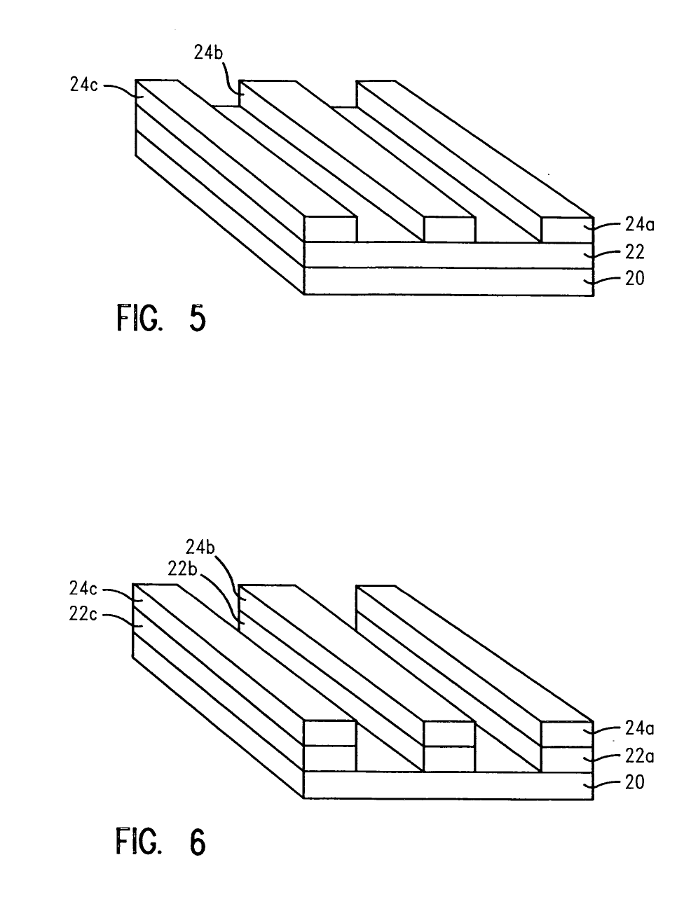

Subsequently, the resist and ARC layers are removed leaving the hard mask layer with the feature formed by portions 24a, 24b and 24c as shown in FIG. 5. Thereafter, the hard mask layer is then used to form the feature in the polysilicon layer, as shown in FIG. 6. Alternatively, in the absence of the hard mask layer, the resist and ARC layers can be used to directly pattern the gate stack. For example, the present invention may be used on polysilicon gate stacks that do not use intermediate hard mask materials, as well as on metal gate stacks, such as tungsten gates. Tests have shown that, as compared to resist layers that have not been cured, the curing of the resist layer in accordance with the present invention produces smoother sidewalls in the substrate layers. Such differences may be measured by root mean square (rms) roughness, which had been found to decrease from approximately 3.5 nm without curing the resist layer to approximately 2 nm using the resist layer cure of the present invention. Other methods of measuring line width roughness (LWR) with a top down SEM have shown a reading of 5.85 nm without resist layer curing and 4.89 nm after resist layer curing in accordance with the present invention.

Thus the present invention provides an improved method of patterning to improve edge roughness in lithographically produced features. The feature to be etched may be on a FEOL level, such as a contact hole, or on a BEOL level.

While the present invention has been particularly described, in conjunction with a specific preferred embodiment, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

Thus, having described the invention,

What is claimed is:

1. A method of patterning a feature in a substrate to reduce roughness of edges of the feature comprising:
forming a resist layer overlying a substrate;
exposing the resist layer to create an image of a feature;
developing the exposed resist layer to leave a portion of the resist layer that creates the image of the feature;
treating the exposed resist layer with a plasma to cure the portion of the resist layer creating the feature image, the plasma treatment having an ion bombardment level sufficient to reduce the number of C═O and C—O bonds in the resist and insufficient to substantially etch the underlying substrate; and
etching the underlying substrate to create the feature with decreased feature edge roughness compared to a feature made without curing the resist layer with the plasma.

2. The method of claim 1 wherein the resist layer is uncured before treatment with the plasma.

3. The method of claim 1 wherein the plasma is HBr plasma.

4. The method of claim 1 wherein the plasma is HI plasma.

5. The method of claim 1 wherein the etching is performed by plasma treatment.

6. The method of claim 1 wherein the etching is performed using inductive or capacitively-coupled etch tools.

7. The method of claim 4 wherein the plasma etching is performed with the same plasma employed to cure the resist layer portion, except at a higher ion bombardment level.

8. The method of claim 1 further including providing a plasma chamber and placing the resist layer and substrate in the plasma chamber, and wherein the curing and etching take place in the plasma chamber.

9. The method of claim 1 further including trimming the portion of the resist layer creating the feature image prior to cure.

10. The method of claim 1 wherein the underlying substrate is etched through the cured portion of the resist layer to create the feature.

11. The method of claim 1 wherein the resist contains an inorganic species.

12. The method of claim 1 wherein the resist is a Si-containing bilayer resist.

13. The method of claim 1 wherein the substrate comprises a polysilicon layer and a hard mask layer between the resist layer and the polysilicon layer, and further including using the portion of the resist layer creating the feature image to etch openings in the hardmask layer, removing the resist layer portion, and using the etched hard mask layer to etch the polysilicon layer to create the feature.

14. The method of claim 1 wherein the substrate comprises a polysilicon or metal layer with no hard mask layer between the resist layer and the polysilicon or metal layer.

15. The method of claim 1 wherein, during the plasma treatment of the resist layer, selectively removing fast etching portions of the resist layer to leave a more uniformly etching resist layer.

16. The method of claim 1 wherein the substrate in which the feature is to be etched is on a front end of the line (FEOL) level.

17. The method of claim 1 wherein the substrate in which the feature is to be etched is on a back end of the line (BEOL) level.

18. A method of patterning a feature in a substrate to reduce roughness of edges of the feature comprising:
forming a resist layer overlying a substrate;
exposing the resist layer to create an image of a feature;
developing the exposed resist layer to leave a portion of the resist layer that creates the image of the feature, the resist layer being uncured;
providing a plasma chamber;
placing the resist layer and substrate in the plasma chamber;
treating the exposed resist layer with a plasma in the plasma chamber to selectively remove fast etching portions of the resist layer to leave a more uniformly etching resist layer and cure the portion of the resist layer creating the feature image, the plasma treatment having an ion bombardment level sufficient to reduce the number of C═O and C—O bonds in the resist and insufficient to substantially etch the underlying substrate; and
etching the underlying substrate through the cured portion of the resist layer to create the feature with decreased feature edge roughness compared to a feature made without curing the resist layer with the plasma.

19. The method of claim 18 further including a hard mask layer between the resist layer and the substrate, and further including using the portion of the resist layer creating the feature image to etch openings in the hardmask layer, removing the resist layer portion, and using the etched hard mask layer to etch the substrate to create the feature.

20. A method of patterning a feature in a substrate to reduce roughness of edges of the feature comprising:
providing a substrate having an overlying hard mask layer;
forming a resist layer overlying the hard mask layer and substrate;
exposing the resist layer to create an image of a feature;
developing the exposed resist layer to leave a portion of the resist layer that creates the image of the feature;
treating the exposed resist layer with a plasma to cure the portion of the resist layer creating the feature image, the plasma treatment having an ion bombardment level sufficient to reduce the number of C═O and C—O bonds in the resist and insufficient to substantially etch the underlying substrate;
etching the underlying hard mask layer with the exposed and cured resist layer portion to create the feature in the hardmask layer;
removing the exposed and cured resist layer portion; and
using the etched hard mask layer to etch the substrate to create the feature with decreased feature edge roughness compared to a feature made without curing the resist layer with the plasma.
